(19) United States
(12) Patent Application Publication
(10) Pub. No.: US 2024/0431106 A1
(43) Pub. Date: Dec. 26, 2024

(54) SEMICONDUCTOR STORAGE DEVICE AND METHOD FOR MANUFACTURING SEMICONDUCTOR STORAGE DEVICE

(71) Applicant: Kioxia Corporation, Tokyo (JP)

(72) Inventor: Koichi YAMAMOTO, Yokkaichi Mie (JP)

(21) Appl. No.: 18/749,751

(22) Filed: Jun. 21, 2024

(30) Foreign Application Priority Data
Jun. 21, 2023 (JP) 2023-101873

(51) Int. Cl. H10B 43/27

(52) U.S. Cl. CPC H10B 43/27

(57) ABSTRACT

A semiconductor storage device includes a stacked body in which a plurality of conductive layers are stacked one layer apart from each other and which has a staircase portion in which the plurality of conductive layers have been processed into a staircase shape, a first pillar that extends in a stacking direction of the stacked body in a portion of the stacked body different from the staircase portion and forms memory cells at each intersection between the first pillar and at least a part of the plurality of conductive layers, a plurality of second pillars that are arranged with periodicity in the staircase portion and extend in the stacking direction within the stacked body, and a contact having a diameter larger than a distance between the plurality of second pillars, that is disposed in the staircase portion and that is electrically connected to one of the plurality of conductive layers.

### CROSS-REFERENCE TO RELATED APPLICATION(S)

This application is based upon and claims the benefit of priority from Japanese Patent Application No. 2023-101873, filed Jun. 21, 2023, the entire contents of which are incorporated herein by reference.

### FIELD

Embodiments describe herein relate generally to a semiconductor storage device and a method for manufacturing a semiconductor storage device.

### BACKGROUND

In a semiconductor storage device such as a three-dimensional non-volatile memory, a memory cell is formed three-dimensionally in a stacked body in which a plurality of conductive layers are stacked. In order to provide an electrical connection to the conductive layers, a plurality of contacts are disposed, each of which is connected to a portion of the plurality of conductive layers that are processed in a staircase shape. In addition, a plurality of dummy pillars for supporting the stacked body are disposed in the stacked body. In order to avoid contact between the contacts and the dummy pillars, the density of the dummy pillars cannot be increased too much.

### DESCRIPTION OF THE DRAWINGS

FIG. 1 is a cross-sectional view illustrating an example of a schematic configuration of a semiconductor storage device according to an embodiment.

FIGS. 2A to 2C are cross-sectional views illustrating an example of a configuration of a semiconductor storage device according to the embodiment.

FIGS. 3A and 3B are cross-sectional views taken along an XY plane at a height position of any word line in a staircase region of the semiconductor storage device according to the embodiment.

FIGS. 4A to 4D are views sequentially illustrating a part of the procedure of the method for manufacturing a semiconductor storage device according to the embodiment.

FIGS. 5A to 5C are views sequentially illustrating a part of the procedure of the method for manufacturing a semiconductor storage device according to the embodiment.

FIGS. 6A to 6C are views sequentially illustrating a part of the procedure of the method for manufacturing a semiconductor storage device according to the embodiment.

FIGS. 7A to 7C are views sequentially illustrating a part of the procedure of the method for manufacturing a semiconductor storage device according to the embodiment.

FIGS. 8A to 8C are views sequentially illustrating a part of the procedure of the method for manufacturing a semiconductor storage device according to the embodiment.

FIGS. 9A to 9D are views sequentially illustrating a part of the procedure of the method for manufacturing a semiconductor storage device according to the embodiment.

FIGS. 10A to 10C are views sequentially illustrating a part of the procedure of the method for manufacturing a semiconductor storage device according to the embodiment.

FIGS. 11A to 11C are views sequentially illustrating a part of the procedure of the method for manufacturing a semiconductor storage device according to the embodiment.

FIGS. 12A to 12F are enlarged cross-sectional views taken along an X direction illustrating the formation process of the contact of the semiconductor storage device according to the embodiment and the comparative example.

### DETAILED DESCRIPTION

Embodiments provide a semiconductor storage device capable of increasing the density of dummy pillars to protect against the collapse of a stacked body in the semiconductor storage device, and a method for manufacturing the semiconductor storage device.

In general, according to one embodiment, a semiconductor storage device includes a stacked body in which a plurality of conductive layers are stacked one layer apart from each other and which has a staircase portion in which the plurality of conductive layers have been processed into a staircase shape, a first pillar that extends in a stacking direction of the stacked body in a portion of the stacked body different from the staircase portion and forms memory cells at each intersection between the first pillar and at least a part of the plurality of conductive layers, a plurality of second pillars that are arranged with periodicity in the staircase portion and extend in the stacking direction within the stacked body, and a contact that is disposed in the staircase portion and that is electrically connected to one of the plurality of conductive layers. The plurality of second pillars are arranged with periodicity in two orthogonal directions when viewed from the stacking direction, and the contact has a diameter larger than a distance between the plurality of second pillars.

Hereinafter, embodiments of the present disclosure will be described in detail with reference to the drawings. Further, the present disclosure is not limited to the following embodiment. The elements in the following embodiments include those that can be easily implemented by those skilled in the art or those that are substantially the same.

### Configuration Example of Semiconductor Storage Device

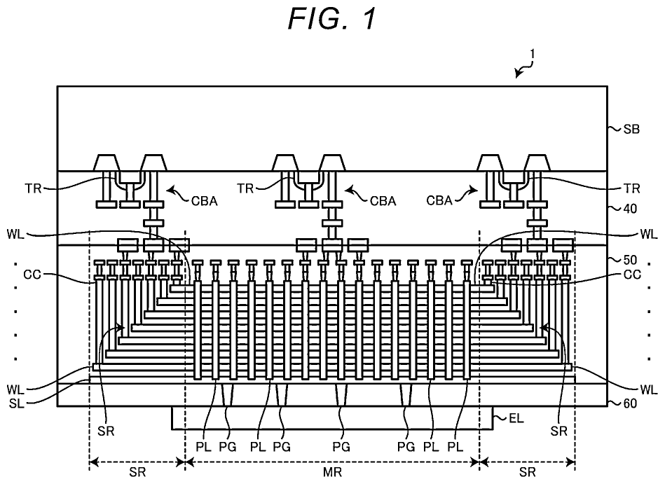

FIG. 1 is a cross-sectional view illustrating an example of a schematic configuration of a semiconductor storage device 1 according to an embodiment. However, in FIG. 1, hatching is omitted in consideration of the visibility of the drawing.

As illustrated in FIG. 1, the semiconductor storage device 1 includes a semiconductor substrate SB on which an electrode film EL, a source line SL, a plurality of word lines WL, and a peripheral circuit CBA are provided in order from the lower side of the drawing.

The source line SL is disposed on the electrode film EL with an insulating layer 60 interposed therebetween. A plurality of plugs PG are disposed in the insulating layer 60, and the source line SL and the electrode film EL are electrically conducted to each other through the plugs PG. Although not illustrated, an electrode pad for supplying power and a signal to the semiconductor storage device 1 from the outside is provided in the same layer as the electrode film EL. A plurality of word lines WL are stacked above the source line SL.

A memory region MR is disposed at a central portion of the plurality of word lines WL, and staircase regions SR are disposed at both end portions of the plurality of word lines WL, respectively.

A plurality of pillars PL penetrating the plurality of word lines WL in a stacking direction are disposed in the memory region MR. A lower end of the pillar PL reaches the source line SL. A plurality of memory cells are formed at intersections of the pillar PL and the word line WL. Thereby, the semiconductor storage device 1 is configured as, for example, a three-dimensional non-volatile memory in which the memory cells are disposed in three dimensions in the memory region MR.

In the staircase region SR, the plurality of word lines WL are processed into a staircase shape and terminate. At this time, as the plurality of word lines WL that configure a terrace portion move from an upper layer side to a lower layer side as the word lines WL move away from the memory region MR, the height position of the terrace portion moves toward the source line SL side.

A contact CC connected to the word line WL of each layer is disposed in the terrace portion of each step of the plurality of word lines WL. An electrical connection to the word lines WL and the like, which are stacked in multiple layers, is individually made through the contacts CC.

More specifically, through the contacts CC, a write voltage, a read voltage, and the like are applied to the memory cells provided in the memory region MR at the central portion of the plurality of word lines WL through the word lines WL at the same height position as the memory cells.

The plurality of word lines WL, the plurality of pillars PL, and the plurality of contacts CC are covered with the insulating layer 50. The insulating layer 50 also extends around the configurations.

The semiconductor substrate SB above the insulating layer 50 is, for example, a silicon substrate or the like. A peripheral circuit CBA including a transistor TR, a wiring, and the like is disposed on a surface of the semiconductor substrate SB. Various voltages applied through the contact CC to the memory cell are controlled by the peripheral circuit CBA electrically connected to the contacts CC. Thereby, the peripheral circuit CBA controls the electrical operation of the memory cell.

By bonding an insulating layer 40 covering the peripheral circuit CBA to the insulating layer 50 covering the plurality of word lines WL, and the like, the semiconductor storage device 1 has a configuration including the plurality of word lines WL, the plurality of pillars PL, and the plurality of contacts CC, and the peripheral circuit CBA.

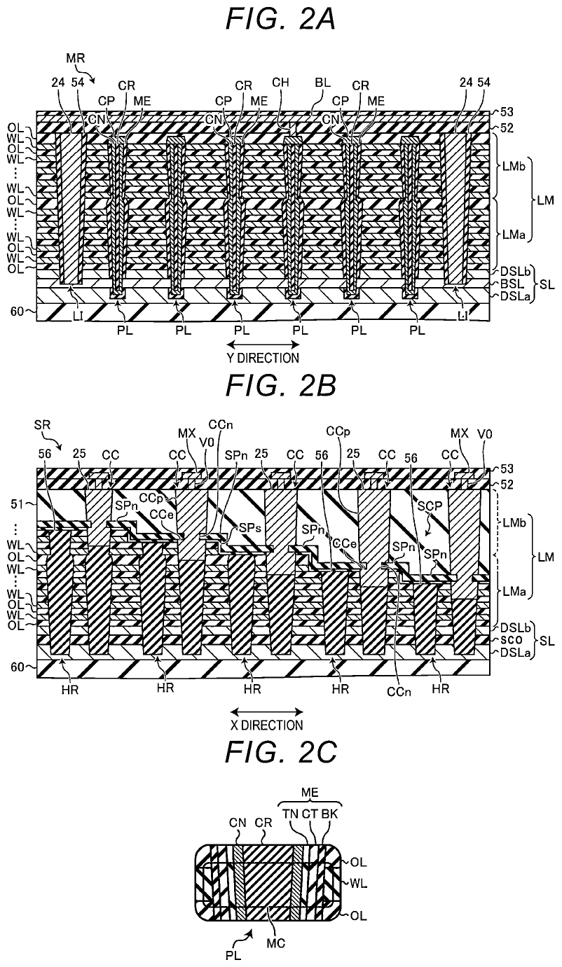

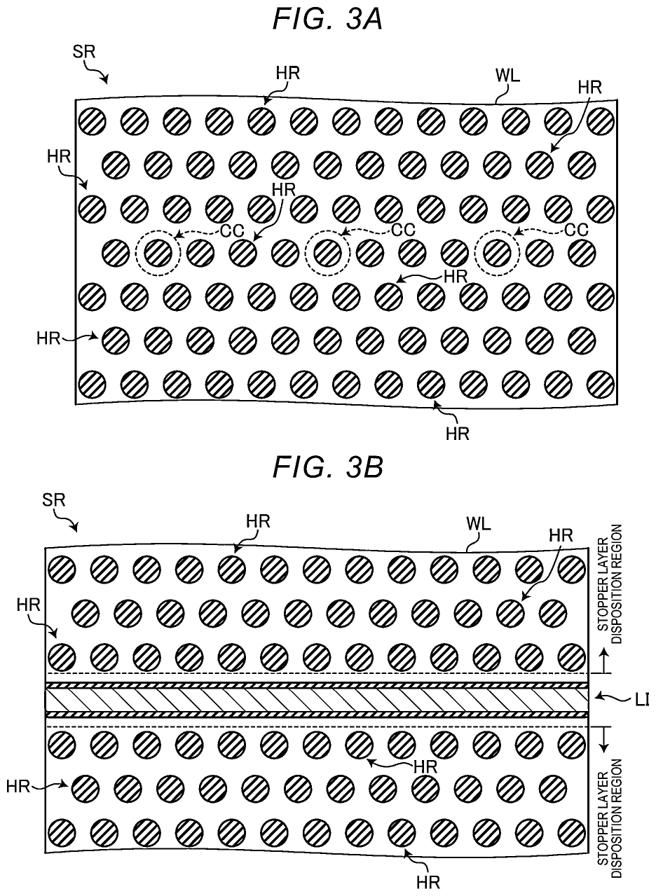

Next, a detailed configuration example of the semiconductor storage device 1 will be described with reference to FIGS. 2A to 3B.

FIGS. 2A to 2C are cross-sectional views illustrating an example of a configuration of the semiconductor storage device 1 according to the embodiment. More specifically, FIG. 2A is a cross-sectional view taken along the Y direction in the memory region MR of the semiconductor storage device 1. FIG. 2B is a cross-sectional view taken along the X direction in the staircase region SR of the semiconductor storage device 1. FIG. 2C is an enlarged cross-sectional view of the pillar PL at a height position of any word line WL.

In FIGS. 2A and 2B, a structure below the insulating layer 60 and a structure above the insulating layer 53 to be described later are omitted.

In addition, in the present specification, both the X direction and the Y direction are directions along a surface of the word line WL, and the X direction and the Y direction are orthogonal to each other. A direction of current flow through the word line WL may be referred to as a first direction, and the first direction is a direction along the X direction. Further, a direction intersecting the first direction may be referred to as a second direction, and the second direction is a direction along the Y direction. However, since the semiconductor storage device 1 may include a manufacturing error, the first direction and the second direction are not necessarily orthogonal to each other.

In addition, in the present specification, a direction that a terrace surface of each step of the word line WL in the staircase region SR faces is defined as an upward direction in the semiconductor storage device 1.

As illustrated in FIG. 2A, the source line SL has a multilayer structure in which, for example, a lower source line DSLa, an intermediate source line BSL, and an upper source line DSLb are stacked in this order on the insulating layer 60. Moreover, the intermediate source line BSL is disposed below the memory region MR of the stacked body LM.

The lower source line DSLa, the intermediate source line BSL, and the upper source line DSLb are, for example, a polysilicon layer or the like. Among them, at least the intermediate source line BSL may be a conductive polysilicon layer or the like in which an impurity is diffused.

Further, the source line SL is connected to the peripheral circuit CBA via the electrode film EL by a through contact (not illustrated) extending from the electrode film EL to the peripheral circuit CBA through the above-described insulating layer 50 outside the stacked body LM.

The stacked body LM is disposed on the source line SL. The stacked body LM includes stacked bodies LMa and LMb in which a plurality of word lines WL and a plurality of insulating layers OL are alternately stacked one layer by layer.

The stacked body LMa is disposed above the source line SL. One or more select gate lines may be disposed in a layer lower than the lowermost word line WL of the stacked body LMa. The stacked body LMb is disposed on the stacked body LMa. One or more select gate lines may be disposed in a layer higher than the uppermost word line WL of the stacked body LMb.

Furthermore, the number of layers of the word lines WL and the select gate lines in the stacked body LM is not limited to any particular number. The word lines WL and the select gate lines are, for example, a tungsten layer, a molybdenum layer, or the like. The insulating layer OL is, for example, a silicon oxide layer.

An upper surface of the stacked body LM is covered with an insulating layer 52. The insulating layer 52 is covered with an insulating layer 53. The insulating layers 52 and 53 are each a part of the insulating layer 50 in FIG. 1 together with the insulating layer 51 to be described below.

As described above, the stacked body LM is divided in the Y direction by a plurality of plate-shaped contacts LI. That is, each of the plate-shaped contacts LI is arranged in the Y direction, and extends in the stacking direction and the X direction.

The plate-shaped contact LI continuously extends from one end portion to the other end portion in the X direction of the stacked body LM within the stacked body LM. In addition, the plate-shaped contact LI penetrates the stacked body LM and the upper source line DSLb, and reaches the intermediate source line BSL in the memory region MR.

Each of the plate-shaped contacts LI includes an insulating layer 54 and a conductive layer 24. The insulating layer 54 is, for example, a silicon oxide layer. The conductive layer 24 is, for example, a tungsten layer or a conductive polysilicon layer.

The insulating layer 54 covers the side wall of the plate-shaped contact LI facing the Y direction. The conductive layer 24 is filled inside the insulating layer 54 and is electrically connected to the source line SL including the intermediate source line BSL. However, instead of the plate-shaped contact LI, a plate-shaped member which is filled with an insulating layer may penetrate the stacked body LM and extend in the direction along the X direction, so that the stacked body LM may be divided in the Y direction.

A plurality of pillars PL are disposed in a dispersed manner in the memory region MR, the pillars PL reaching the lower source line DSLa through the stacked body LM, the upper source line DSLb, and the intermediate source line BSL.

The pillars PL are arranged with periodicity in, for example, a direction along two directions of the X direction and the Y direction when viewed in the stacking direction of the stacked body LM. For example, the plurality of pillars PL are arranged in a staggered shape. Each of the pillars PL has a shape such as a circular shape, an elliptical shape, or an oval shape as a cross-sectional shape in a direction along the stacking direction of the stacked body LM, that is, in a direction along the XY plane.

In addition, the pillar PL has a tapered shape in which the XY cross-sectional area are reduced from the upper layer side toward the lower layer side in the portion that penetrates the stacked body LMa and the portion that penetrates the stacked body LMb, respectively. Alternatively, the pillar PL has, for example, a bow shape in which the XY cross-sectional area thereof is maximum at a predetermined position between the upper layer side and the lower layer side in the portion penetrating the stacked body LMa and the portion penetrating the stacked body LMb, respectively.

Each of the plurality of pillars PL has a memory layer ME that extends in the stacking direction within the stacked body LM, a channel layer CN that penetrates the stacked body LM and is connected to the intermediate source line BSL, a cap layer CP that covers the upper surface of the channel layer CN, and a core layer CR that is a core material of the pillar PL.

As illustrated in FIG. 2C, the memory layer ME has a multilayer structure in which a block insulating layer BK, a charge storage layer CT, and a tunnel insulating layer TN are stacked in this order from the outer peripheral side of the pillar PL. More specifically, the memory layer ME is disposed on a side surface of the pillar PL except at a depth position of the intermediate source line BSL. In addition, the memory layer ME is also disposed on a bottom surface of the pillar PL reaching the lower source line DSLa.

The channel layer CN is inside the memory layer ME, penetrates the stacked body LM, the upper source line DSLb, and the intermediate source line BSL, and reaches the lower source line DSLa. More specifically, the channel layer CN is disposed on the side surface and the bottom surface of the pillar PL and surrounded by the memory layer ME. A part of the channel layer CN is in contact with the intermediate source line BSL on the side surface thereof, and thus is electrically connected to the source line SL including the intermediate source line BSL. The core layer CR is filled on the inner side of the channel layer CN.

In addition, each of the plurality of pillars PL has a cap layer CP at an upper end portion. The cap layer CP is disposed on the upper end portion of the pillar PL at least to cover the upper end portion of the channel layer CN and is connected to the channel layer CN. In addition, the cap layer CP is connected to a bit line BL disposed in the insulating layer 53 via a plug CH disposed in the insulating layer 52. The bit line BL extends above the stacked body LM in the Y direction.

In FIG. 2A, the plug CH is connected to only one of the six pillars PL. The rest of pillars PL are each connected to one of other bit lines BL extending in the direction along the Y direction in parallel to the bit line BL illustrated in FIG. 2A at a position different from the cross section illustrated in FIG. 2A via a respective plug CH (not illustrated in FIG. 2A).

The block insulating layer BK and the tunnel insulating layer TN of the memory layer ME, and the core layer CR are, for example, a silicon oxide layer. The charge storage layer CT of the memory layer ME is, for example, a silicon nitride layer. The channel layer CN and the cap layer CP are, for example, a semiconductor layer such as a polysilicon layer or an amorphous silicon layer.

As illustrated in FIG. 2C, the memory cell MC is formed in each portion of the pillar PL side surface facing the individual word lines WL to have the above-described configuration. Data is written to and read from the memory cell MC by applying a predetermined voltage to the word line WL.

In addition, when the stacked body LM has the select gate lines above and below the word line WL, the select gates are respectively formed in the portions facing the select gate lines. By applying a predetermined voltage from each of the select gate lines, the select gate can be turned on or off, and the memory cell MC of the pillar PL to which the select gate belongs can be set to a selected state or an unselected state.

As illustrated in FIG. 2B, the staircase region SR has a staircase portion SCP in which a plurality of word lines WL are processed in a staircase shape. FIG. 2B illustrates a part of the plurality of word lines WL processed in a staircase shape.

A stopper layer SPs covering the staircase portion SCP along the staircase shape of the staircase portion SCP and a stopper layer SPn are disposed in this order on the staircase portion SCP.

The staircase portion SCP is further covered with the insulating layer 51 above the stopper layers SPs and SPn. The insulating layer 51 reaches at least a height position of the top layer of the stacked body LM, and the insulating layers 52 and 53 also cover the upper surface of the insulating layer 51. As described above, the insulating layer 51 is a part of the insulating layer 50 in FIG. 1.

Here, the stopper layer SPs and the insulating layer 51 are, for example, a silicon oxide layer. In addition, the stopper layer SPn is, for example, a silicon nitride layer.

In addition, in the staircase region SR, the source line SL includes an intermediate insulating layer SCO interposed between the upper source line DSLb and the lower source line DSLa instead of the intermediate source line BSL. The intermediate insulating layer SCO is, for example, a silicon oxide layer.

Therefore, the plate-shaped contact LI reaches the intermediate insulating layer SCO by penetrating the insulating layer 51, the stacked body LM, and the upper source line DSLb in the staircase region SR.

In addition, the plurality of contacts CC and a plurality of columnar portions HR are disposed in the staircase region SR. As will be described later, the columnar portions HR provide structural support when the stacked body LM is formed from a stacked body in which a sacrificial layer and an insulating layer are stacked, and do not contribute to the function of the semiconductor storage device 1.

The columnar portion HR reaches the lower source line DSLa by penetrating the stacked bodies LMb and LMa processed in a staircase shape, the upper source line DSLb, and the intermediate insulating layer SCO.

More specifically, each of the columnar portions HR extends within the stacked body LM from the individual terrace surface of the staircase portion SCP of the word line WL and the insulating layer OL that is lower than the terrace surface. Therefore, the dimension of the columnar portion HR in an extending direction from the portion of the upper layer side word line WL processed in a staircase shape to the portion of the lower layer side word line WL processed in a staircase shape, is shortened.

The columnar portions HR are distributed over the entire staircase portion SCP and are arranged with periodicity in a direction along, for example, two directions of the X direction and the Y direction when viewed in the stacking direction of the stacked body LM. As an example, the plurality of columnar portions HR are arranged in a grid shape or a staggered shape. Each of the columnar portions HR has a shape such as a circular shape, an elliptical shape, or an oval shape as a cross-sectional shape in a direction along the XY plane.

In addition, when the columnar portion HR that penetrates the word line WL on the relatively upper layer side is taken as an example, the columnar portion HR has a tapered shape in which the diameter and the cross-sectional area are reduced from the upper layer side toward the lower layer side in a portion that penetrates the stacked body LMa and a portion that penetrates the stacked body LMb, respectively. Alternatively, the columnar portion HR has, for example, a bow shape in which the XY cross-sectional area thereof is maximum at a predetermined position between the upper layer side and the lower layer side in the portion penetrating the stacked body LMa and the portion penetrating the stacked body LMb, respectively.

The columnar portion HR is made entirely of a single layer of the insulating layer 56 such as a silicon oxide layer. That is, the columnar portion HR includes the insulating layer 56 made with substantially a single material. Here, the meaning of the substantially single material may include a case where the element ratio of the elements of the columnar portions HR is different in one columnar portion HR or between the plurality of columnar portions HR, and a case where the type and the amount of the impurities contained therein are different, and may also include a case where a void is allowed to be provided in the columnar portion HR of the single material.

Since the columnar portion HR is a single layer of the insulating layer 56 as described above, the columnar portion HR may not have an electrical influence on other configurations, and interference with the plate-shaped contact LI and the contact CC, which are adjacent to the columnar portion HR, is allowed.

Moreover, at the same height position of the stacked body LM, the XY cross-sectional area of the columnar portion HR is larger than, for example, the XY cross-sectional area of the pillar PL. In addition, the pitch between the plurality of columnar portions HR is larger than, for example, the pitch between the plurality of pillars PL, and the density of the columnar portions HR arranged per unit area of the word line WL in the stacked body LM is lower than the density of the pillars PL arranged per unit area of the word line WL.

In this way, for example, by configuring the cross-sectional area of the pillar PL to be smaller than that of the columnar portion HR and by making the pitch narrower, a large number of memory cells MC can be formed at a high density in the stacked body LM of a predetermined size, and the storage capacity of the semiconductor storage device 1 can be increased. On the other hand, since the columnar portion HR is used exclusively for supporting the stacked body LM, the manufacturing load can be reduced by not making the columnar portion HR to be a precise configuration with a small cross-sectional area and a narrow pitch like the pillar PL, for example.

Each of the individual contacts CC is connected to the word line WL immediately below the insulating layer OL, which forms the terrace surface of each step of the staircase portion SCP, by penetrating the insulating layer 51 and the stopper layers SPn and SPs. At this time, the contact CC has, for example, a diameter larger than a distance between the columnar portions HR adjacent to each other, and a part or the entirety of a lower end portion of contact CC is in contact with a part or the entirety of an upper end portion of the at least one columnar portion HR.

In addition, each of the contacts CC includes an extension portion CCp extending within the insulating layer 51, a penetrating portion CCn penetrating the stopper layer SPn, and a connection portion CCe penetrating the insulating layer OL serving as a terrace surface and connected to the word line WL. At this time, the connection portion CCe may also penetrate the word line WL to be connected and may be connected to the word line WL on the side surface of the connection portion CCe.

The extension portion CCp has a first diameter at the lower end portion thereof. The penetrating portion CCn has a second diameter smaller than the first diameter. The connection portion CCe has a third diameter at the upper end portion thereof larger than the second diameter. That is, the contact CC has a shape in which the diameter is reduced in the penetrating portion CCn.

The contact CC configured as described above has a conductive layer 25 such as a tungsten layer or a copper layer, and the conductive layer 25 continuously extends from the extension portion CCp through the penetrating portion CCn to the connection portion CCe.

The conductive layer 25 of each contact CC is connected to an upper layer wiring MX disposed in the insulating layer 53 via a plug V0 disposed in the insulating layer 52. The upper layer wiring MX is electrically connected to the peripheral circuit CBA (refer to FIG. 1) described above.

With such a configuration, the word lines WL of each layer can be electrically connected to the peripheral circuit CBA at both end portions of the stacked body LM in the X direction. That is, with the above configuration, the peripheral circuit CBA can apply a predetermined voltage to the memory cell MC via the upper layer wiring MX, the contact CC, the word line WL, and the like, and can operate the memory cell MC as a storage element.

FIGS. 3A and 3B are cross-sectional views taken along the XY plane at a height position of any word line WL in the staircase region SR of the semiconductor storage device 1 according to the embodiment.

More specifically, FIG. 3A is an XY cross-sectional view of a region in which the contact CC is disposed in the staircase region SR of the semiconductor storage device 1. FIG. 3B is an XY cross-sectional view of a region in which the plate-shaped contact LI is disposed in the staircase region SR of the semiconductor storage device 1. FIGS. 3A and 3B illustrate an example in which a plurality of columnar portions HR are arranged in a staggered manner.

As illustrated in FIG. 3A, the plurality of columnar portions HR are arranged with periodicity in two directions along the X direction and the Y direction, and are arranged in a staggered manner, for example. The periodicity of the columnar portion HR is also maintained at the location of the contact CC. Therefore, at least in a peripheral region of the contact CC illustrated in FIG. 3A, the distance and the pitch between the columnar portions HR adjacent to each other are substantially constant.

Here, the distance between the columnar portions HR adjacent to each other is a distance between the outer edge portions of the columnar portions HR closest to each other. The pitch between the columnar portions HR adjacent to each other is a distance between the center points of the cross-sectional shapes of the columnar portions HR in the XY plane.

In the example of FIG. 3A, six columnar portions HR are disposed adjacent to each other around one columnar portion HR. The distances between the columnar portion HR located at the center and the six columnar portions HR around the columnar portion HR are all substantially equal, and the pitches are also all substantially equal.

Further, at this time, the contact CC has a diameter larger than a distance between the columnar portions HR adjacent to each other. In addition, at least the diameter of the upper end portion of the contact CC is larger than the diameter of each of the columnar portions HR.

As a result of the columnar portion HR being disposed in this way, in the example of FIG. 3A, one columnar portion HR is disposed at a disposition location of the contact CC such that the center points of the cross-sectional shapes of the columnar portions HR substantially coincide with each other in the XY plane.

As described above, the periodicity of the columnar portion HR is maintained even at the location of the contact CC, so that the columnar portion HR is arranged at high density per unit area.

As illustrated in FIG. 3B, the plurality of columnar portions HR are also periodically arranged in the vicinity of the plate-shaped contact LI, for example, in a staggered arrangement. However, in order to avoid interference with the plate-shaped contact LI, the columnar portions HR are not arranged at a position where the plate-shaped contact LI is located. Thereby, the periodicity of the columnar portion HR may be disturbed in the vicinity of the plate-shaped contact LI.

In addition, at least the stopper layer SPn among the above-described stopper layers SPn and SPs is not disposed between broken lines indicated in FIG. 3B so as to avoid the location of the plate-shaped contact LI. That is, the plate-shaped contact LI reaches each terrace surface of the staircase portion SCP without penetrating the stopper layer SPn.

### Method for Manufacturing Semiconductor Storage Device

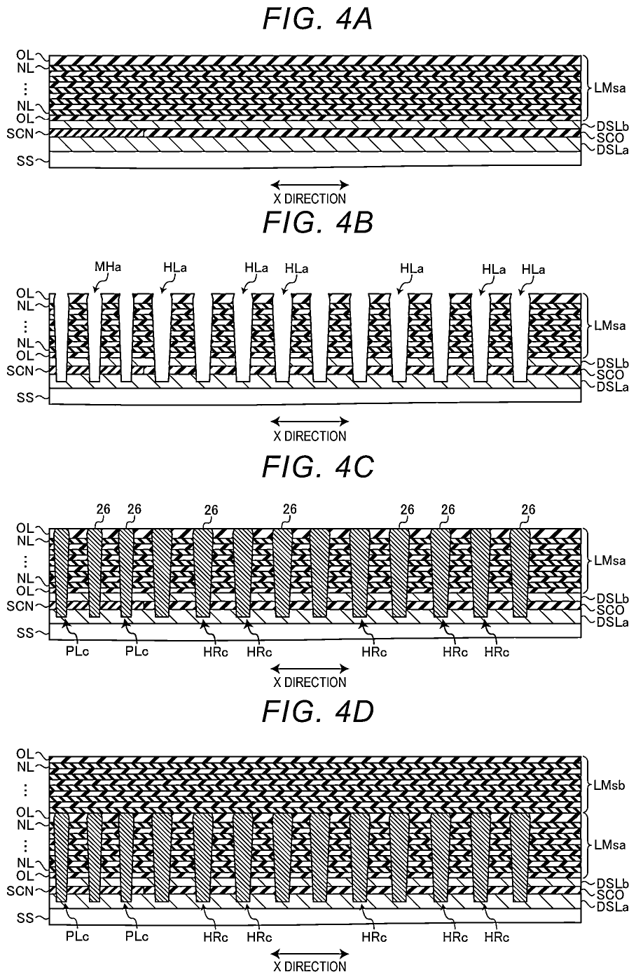

Next, a method for manufacturing a semiconductor storage device 1 according to the embodiment will be described with reference to FIGS. 4A to 11C. FIGS. 4A to 11C are views sequentially illustrating a part of the procedure of the method for manufacturing the semiconductor storage device 1 according to the embodiment.

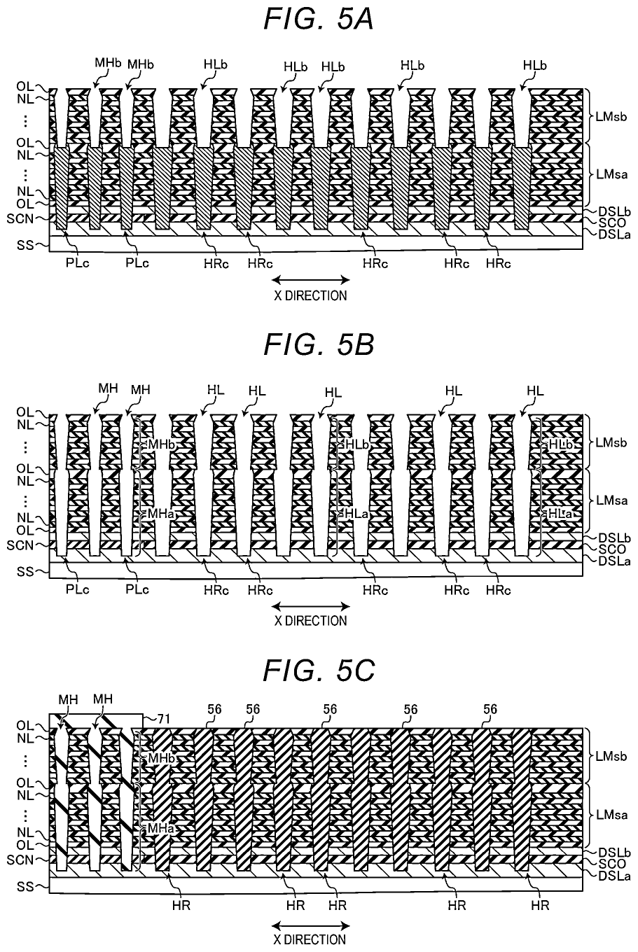

First, FIGS. 4A to 5C illustrate the stacked bodies LMsa and LMsb each of which represents the stacked body LM before the word line WL is formed and a state in which various configurations are formed in the stacked bodies LMsa and LMsb. FIGS. 4A to 5C are cross-sectional views taken along the X direction of a region that is to be the memory region MR and the staircase region SR later.

As illustrated in FIG. 4A, the lower source line DSLa, an intermediate sacrificial layer SCN or the intermediate insulating layer SCO, and the upper source line DSLb are formed in this order on a supporting substrate SS.

As the supporting substrate SS, a semiconductor substrate such as a silicon substrate, an insulating substrate such as a ceramic substrate, or a conductive substrate may be used. The insulating layer 60 (refer to FIGS. 2A to 2C and the like) described above may be formed on the upper surface side of the supporting substrate SS.

The intermediate sacrificial layer SCN is formed in a region on the supporting substrate SS that is to be the memory region MR later, and the intermediate insulating layer SCO is formed in a region on the supporting substrate SS that is to be the staircase region SR later. The intermediate sacrificial layer SCN is, for example, a silicon nitride layer or the like, and is a layer that is later replaced with a polysilicon layer or the like to become the intermediate source line BSL. The intermediate insulating layer SCO is, as described above, for example, a silicon oxide layer.

In addition, a stacked body LMsa in which a plurality of insulating layers NL and a plurality of insulating layers OL are alternately stacked one layer by layer is formed on the upper source line DSLb. The insulating layer NL is, for example, a silicon nitride layer or the like, and functions as a sacrificial layer to be replaced with a conductive material to become the word line WL later.

As illustrated in FIG. 4B, for example, a plurality of memory holes MHa and a plurality of holes HLa extending in the stacking direction are collectively formed in the stacked body LMsa. The memory hole MHa is a portion that is to be a lower structure of the pillar PL later. The hole HLa is a portion that is to be a lower structure of the columnar portion HR later.

As illustrated in FIG. 4C, the memory holes MHa and the holes HLa are filled with a sacrificial layer 26 such as an amorphous silicon layer or a CVD-carbon layer.

Thereby, a pillar PLc in which the plurality of memory holes MHa are filled with the sacrificial layer 26 is formed in the region that is to be the memory region MR later. In addition, a columnar portion HRc in which the plurality of holes HLa are filled with the sacrificial layer 26 is formed in a region that is to be the staircase region SR later.

As illustrated in FIG. 4D, the stacked body LMsb is formed by covering the stacked body LMsa with the plurality of insulating layers NL and the plurality of insulating layers OL being alternately stacked one layer by layer. The insulating layer NL of the stacked body LMsb is replaced with a conductive layer later to become the word line WL.

As illustrated in FIG. 5A, for example, a plurality of memory holes MHb and a plurality of holes HLb extending in the stacking direction are collectively formed in the stacked body LMsb. The memory hole MHb is a portion that is to be an upper structure of the pillar PL later. The hole HLb is a portion that is to be an upper structure of the columnar portion HR later.

The plurality of memory holes MHb are disposed in a region that is to be the memory region MR later, and respectively reach the upper end portions of the pillars PLc formed in the stacked body LMsa, penetrating the stacked body LMsb.

The plurality of holes HLb are disposed in a region that is to be a staircase region SR later, and respectively reach the upper end portion of the columnar portion HRc formed in the stacked body LMsa by penetrating the stacked body LMsb.

As illustrated in FIG. 5B, the sacrificial layer 26 is removed from the memory hole MHb, and the pillar PLc and the columnar portion HRc at the bottom of the hole HLb.

As a result, a plurality of memory holes MH are formed, each having the memory hole MHa open at the bottom of the plurality of memory hole MHb, penetrating the stacked bodies LMsb and LMsa, the upper source line DSLb, and the intermediate sacrificial layer SCN, and reaching the lower source line DSLa. In addition, a plurality of holes HL are formed, each having the hole HLa open at the bottom of the plurality of holes HLb, penetrating the insulating layer 51, the stacked bodies LMsb and LMsa, the upper source line DSLb, and the intermediate insulating layer SCO, and reaching the lower source line DSLa.

When the sacrificial layer 26 filling the pillar PLc and the columnar portion HRc is a CVD-carbon layer or the like, the sacrificial layer 26 may be collectively removed from the pillar PLc and the columnar portion HRc when the mask pattern and the like used in the processing of FIG. 5A described above are removed by ashing using oxygen plasma or the like.

As illustrated in FIG. 5C, the plurality of memory holes MH are covered with a mask layer such as a photoresist layer, and the hole HL is filled with the insulating layer 56 such as a silicon oxide layer. Thereby, a columnar portion HR penetrating the stacked bodies LMsa and LMsb is formed.

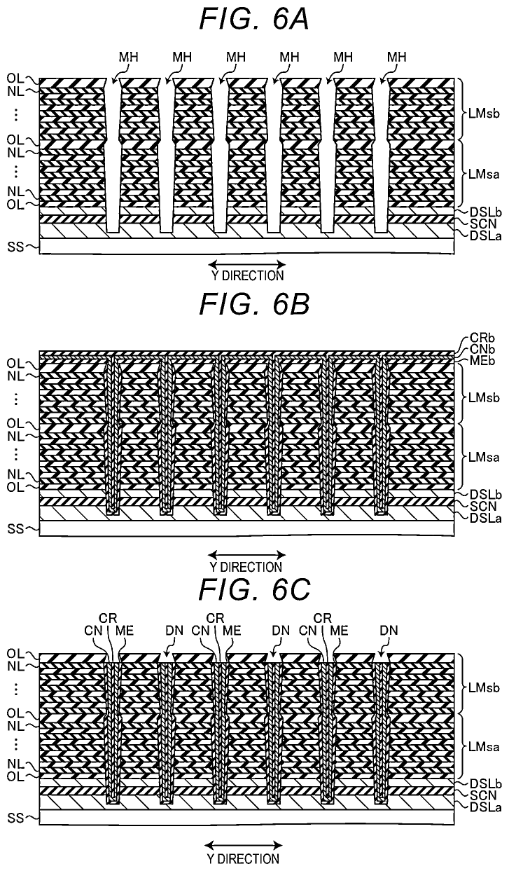

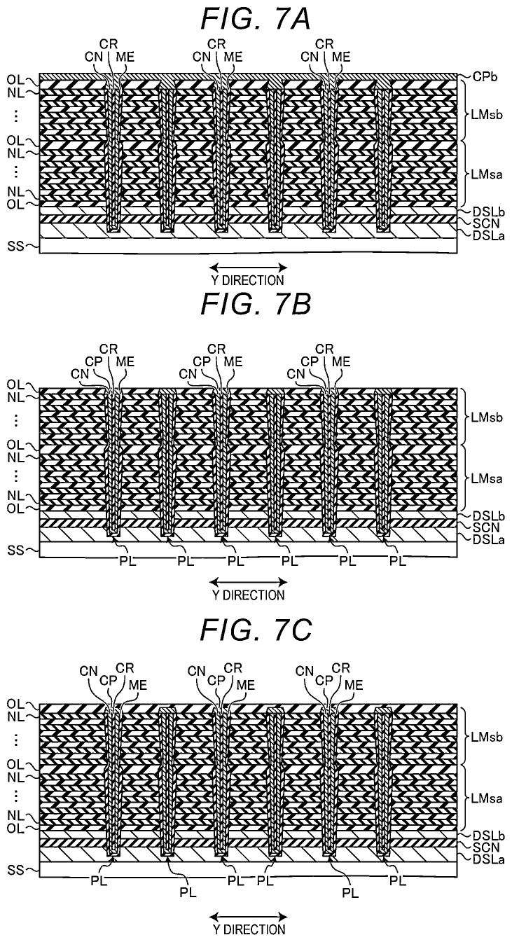

Next, a state in which the pillar PL is formed will be described with reference to FIGS. 6A to 7C.

FIGS. 6A to 7C are cross-sectional views taken along the Y direction of a region that is to be the memory region MR later, and illustrate a cross section corresponding to the cross section of FIG. 2A described above.

As illustrated in FIG. 6A, the plurality of memory holes MH penetrating the stacked bodies LMsa and LMsb have been formed in a region that is to be the memory region MR later.

As illustrated in FIG. 6B, a multilayer insulating layer MEb, a semiconductor layer CNb, and an insulating layer CRb are formed in this order in the memory hole MH. Thereby, the multilayer insulating layer MEb and the semiconductor layer CNb are disposed on a side surface of the memory hole MH and on the bottom surface on which the lower source line DSLa is exposed, and the center portion of the memory hole MH is filled with the insulating layer CRb.

The multilayer insulating layer MEb is an insulating layer having a multilayer structure that is to be the memory layer ME later. The semiconductor layer CNb is a layer that is to be a channel layer CN later. The insulating layer CRb is a silicon oxide layer or the like that is to be the core layer CR later.

The multilayer insulating layer MEb, the semiconductor layer CNb, and the insulating layer CRb are also formed in this order on the upper surface of the stacked body LMsb.

As illustrated in FIG. 6C, the insulating layer CRb, the semiconductor layer CNb, and the multilayer insulating layer MEb are subsequently etched back to be removed from the upper surface of the stacked body LMsb, and a depression DN is formed at the upper end portion of the memory hole MH.

Thereby, the memory layer ME, the channel layer CN, and the core layer CR are sequentially formed from the outer peripheral side in the memory hole MH.

As illustrated in FIG. 7A, a semiconductor layer CPb is formed in the depression DN at the upper end portion of the memory hole MH. The semiconductor layer CPb is a layer that is to be the cap layer CP later. The semiconductor layer CPb is also formed on the upper surface of the stacked body LMsb.

As illustrated in FIG. 7B, the semiconductor layer CPb on the upper surface of the stacked body LMsb is removed by CMP or the like, and the cap layer CP is formed at the upper end portion of the memory hole MH.

As illustrated in FIG. 7C, the insulating layer OL thinned by CMP or the like on the top layer of the stacked body LMsb is additionally stacked. Thereby, the pillar PL in which the cap layer CP is buried in the top insulating layer OL is formed.

However, at this time, the memory layer ME covers the entire side wall of the pillar PL, and a part of the side surface of the channel layer CN is not exposed from the memory layer ME.

The region that is to be the staircase region SR later is previously formed with the plurality of columnar portions HR, and is hardly affected by the processing of FIGS. 6A to 7C described above. However, by the processing of FIGS. 7B and 7C, the upper end portion of the columnar portion HR is also in a state of being buried in the insulating layer OL on the top layer.

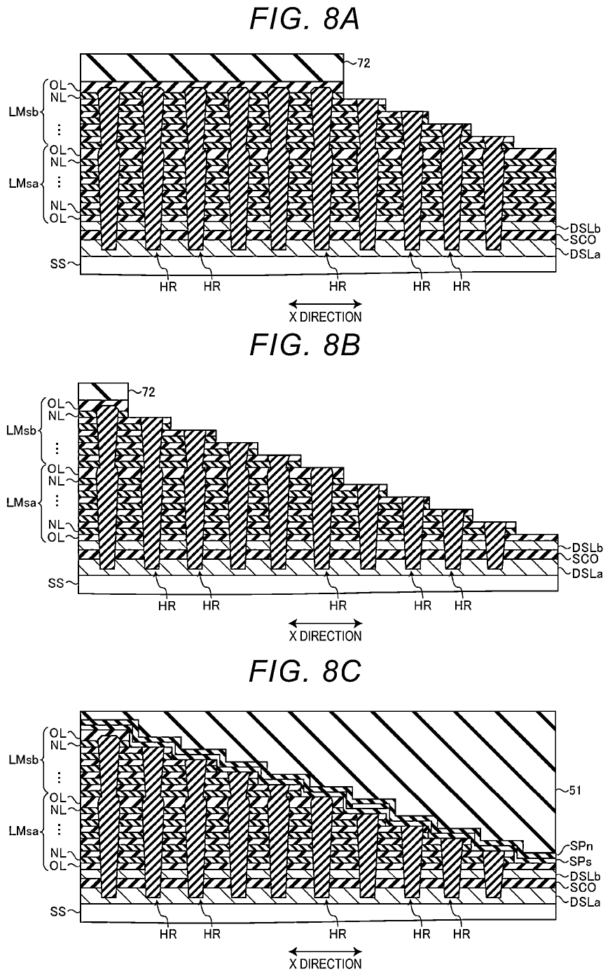

Next, a state in which a staircase structure is formed in a region that is to be a staircase region SR later will be described with reference to FIGS. 8A to 8C. FIGS. 8A to 8C are cross-sectional views taken along the X direction of a region that is to be a staircase region SR later.

As illustrated in FIG. 8A, the insulating layer NL and the insulating layer OL are processed into a staircase shape in a region that is to be the staircase region SR later. Such processing may be performed by repeating a plurality of times slimming of the mask pattern 72 such as a photoresist layer and etching of the insulating layer NL and the insulating layer OL subsequently exposed from the mask pattern 72.

That is, a mask pattern is formed on the upper surface of the stacked body LMsb, and, for example, the insulating layer NL and the insulating layer OL of the exposed portion are etched and removed one layer by layer. In addition, the end portion of the mask pattern is retreated by processing with oxygen plasma or the like to newly expose the upper surface of the stacked body LMsb, and the insulating layer NL and the insulating layer OL are further etched and removed one layer by layer. By repeating such processing a plurality of times, first, the stacked body LMsb is formed with the above-described staircase shape.

As illustrated in FIG. 8B, the repeated process of slimming the mask pattern 72 and etching the insulating layer NL and the insulating layer OL is continued for the stacked body LMsa. Thereby, the stacked body LMsa is also formed with a staircase shape.

Moreover, in the processing of FIGS. 8A and 8B, the columnar portion HR formed by penetrating the stacked bodies LMsa and LMsb is also etched and removed in parallel with the processing of the respective layers of the stacked bodies LMsa and LMsb. Thereby, a plurality of columnar portions HR extending through the insulating layer NL and the insulating layer OL of the lower layer of the terrace surfaces are formed from each of the terrace surfaces of the stacked bodies LMsa and LMsb having the staircase shape.

As illustrated in FIG. 8C, the stopper layers SPs and SPn are formed in this order along the staircase shape of the stacked bodies LMsa and LMsb. The stopper layer SPs is, for example, a silicon oxide layer as described above. The stopper layer SPn is, for example, a silicon nitride layer.

In addition, the stopper layer SPn is removed from a portion that is located at a cross section different from the cross section illustrated in FIG. 8C and that is to be formed with the plate-shaped contact LI later. At this time, the stopper layer SPs may be removed together.

In addition, an insulating layer 51 as a second insulating layer such as a silicon oxide layer covering the staircase shape of the stacked bodies LMsa and LMsb up to the height position of the unprocessed portion of the stacked bodies LMsa and LMsb via the stopper layers SPs and SPn is formed.

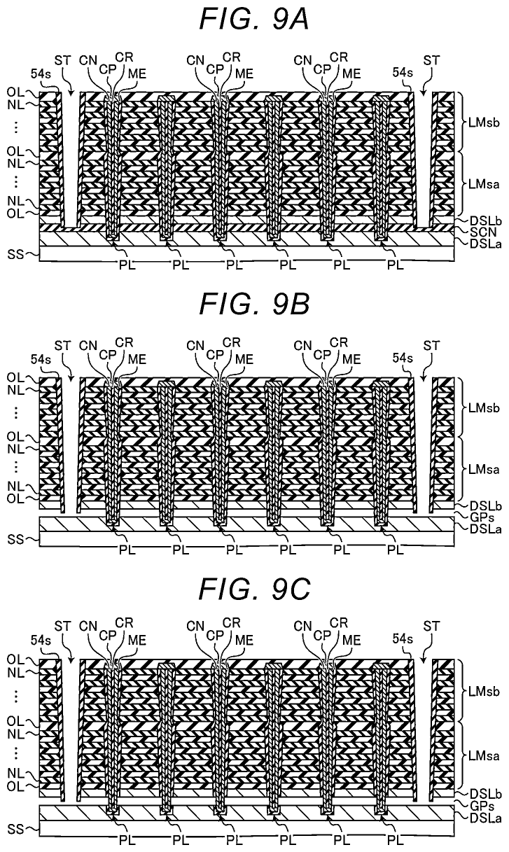

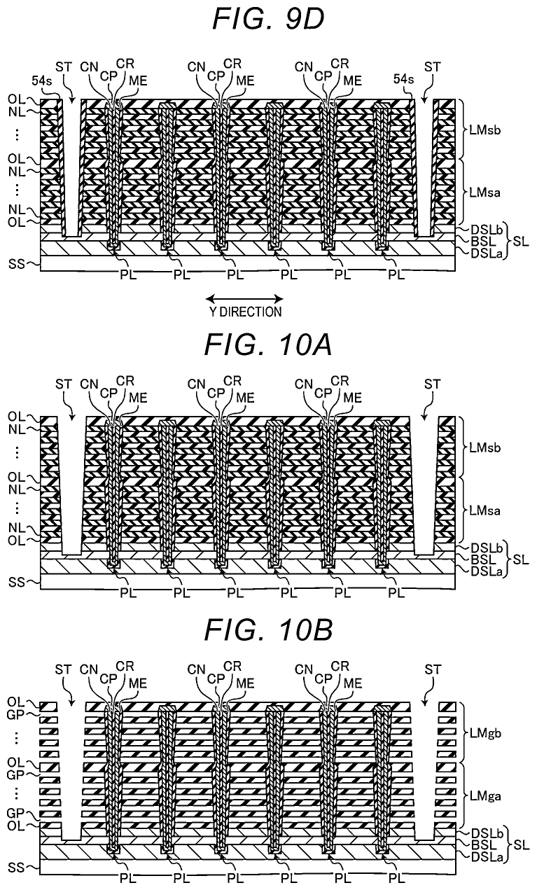

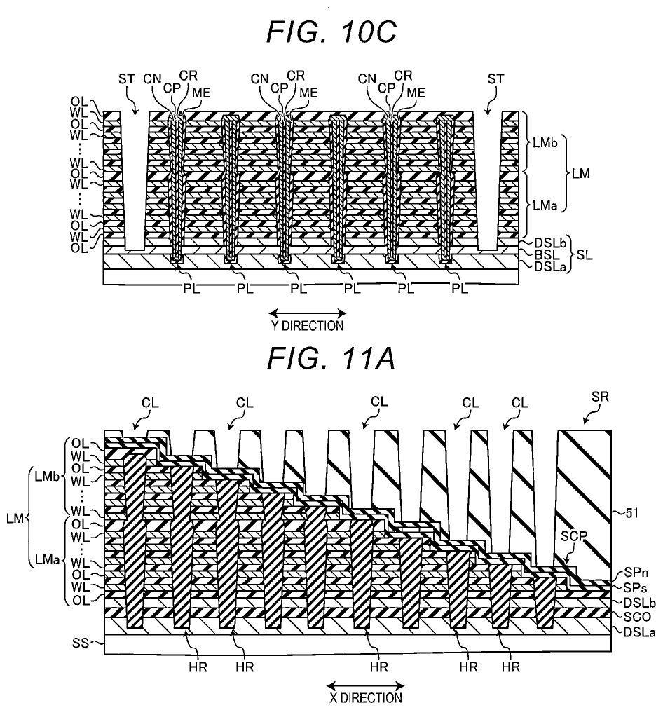

Next, a state in which the source line SL and the word line WL are formed will be described with reference to FIGS. 9A to 10C. FIGS. 9A to 10C are cross-sectional views taken along the Y direction of a region that is to be the memory region MR later, as in FIGS. 6A to 7C described above.

As illustrated in FIG. 9A, a slit ST that penetrates the stacked bodies LMsb and LMsa and the upper source line DSLb, and reaches the intermediate sacrificial layer SCN is formed. In addition, an insulating layer 54s is formed on the side wall facing the Y direction of the slit ST.

The slit ST also extends in the direction along the X direction within the stacked bodies LMsa and LMsb. Therefore, in a region (not illustrated) that is to be the staircase region SR later, the lower end portion of the slit ST reaches the intermediate insulating layer SCO.

As illustrated in FIG. 9B, for example, a removal liquid for the intermediate sacrificial layer SCN such as hot phosphoric acid is allowed to flow into the slit ST whose side wall is protected by the insulating layer 54s to remove the intermediate sacrificial layer SCN interposed between the lower source line DSLa and the upper source line DSLb.

Thereby, a gap layer GPs is formed between the lower source line DSLa and the upper source line DSLb. In addition, a part of the memory layer ME of the outer peripheral portion of the pillar PL is exposed in the gap layer GPs.

At this time, since the side wall of the slit ST is protected by the insulating layer 54s, the insulating layer NL in the stacked bodies LMsa and LMsb is prevented from being removed. In addition, in the region that is to be the staircase region SR later, the intermediate sacrificial layer SCN is not provided between the lower source line DSLa and the upper source line DSLb, and the gap layer GPs is not formed.

As illustrated in FIG. 9C, a chemical solution is appropriately allowed to flow into the gap layer GPs through the slit ST, and the block insulating layer BK, the charge storage layer CT, and the tunnel insulating layer TN (refer to FIG. 2C) of the memory layer ME exposed in the gap layer GPs are subsequently removed. Thereby, the memory layer ME is removed from a part of the side wall of the pillar PL, and a part of the inner channel layer CN is exposed in the gap layer GPs.

As illustrated in FIG. 9D, the gap layer GPs is filled with amorphous silicon or the like by injecting a raw material gas such as amorphous silicon from the slit ST whose side wall is protected by the insulating layer 54s. In addition, the supporting substrate SS is heat-treated to polycrystallize the amorphous silicon filling the gap layer GPs to form an intermediate source line BSL containing polysilicon, or the like.

Thereby, a part of the channel layer CN of the pillar PL is connected to the source line SL on the side surface through the intermediate source line BSL.

At this time, in the region that is to be the staircase region SR later, the gap layer GPs is not formed between the lower source line DSLa and the upper source line DSLb. Therefore, the intermediate source line BSL is not formed.

As illustrated in FIG. 10A, the insulating layer 54s on the side wall of the slit ST is once removed.

As illustrated in FIG. 10B, the insulating layer NL of the stacked bodies LMsa and LMsb is removed by allowing, for example, a removal liquid for the insulating layer NL such as hot phosphoric acid to flow from the slit ST to the inside of the stacked bodies LMsa and LMsb. Thereby, stacked bodies LMga and LMgb having the plurality of gap layers GP from which the insulating layers NL between the insulating layers OL are removed are formed.

The stacked bodies LMga and LMgb including the plurality of gap layers GP have a fragile structure. In a region that is to be the memory region MR later, the plurality of pillars PL support such fragile stacked bodies LMga and LMgb. On the other hand, in the region that is to be the staircase region SR later, the plurality of columnar portions HR support the stacked bodies LMga and LMgb.

With the support structure of the pillar PL and the columnar portion HR, the remaining insulating layer OL is prevented from being bent, and the stacked bodies LMga and LMgb are prevented from being distorted or collapsed.

Furthermore, in the region that is to be the staircase region SR later, the stopper layer SPn is removed from the formation position of the slit ST. Therefore, the slit ST is prevented from being in contact with the stopper layer SPn and being removed even when the stopper layer SPn containing the same material as the insulating layer NL is removed.

In addition, the end surface of the insulating layer NL to be replaced is provided in the step surface of each step of the staircase shape. However, the step surface of each step is covered with the stopper layer SPs that is not affected by the replacement. Therefore, the stopper layer SPn is also prevented from being removed via the end surface of the insulating layer NL of the step surface.

As illustrated in FIG. 10C, a raw material gas of a conductive material such as tungsten or molybdenum is injected from the slit ST into the stacked bodies LMga and LMgb, and the gap layers GP of the stacked bodies LMga and LMgb are filled with the conductive material to form the plurality of word lines WL and the like. Thereby, the stacked body LM as a second stacked body including stacked bodies LMa and LMb in which the plurality of word lines WL and the plurality of insulating layers OL are alternately stacked one layer by layer is formed.

As described above, the process of forming the intermediate source line BSL from the intermediate sacrificial layer SCN and the process of forming the word line WL from the insulating layer NL are also referred to as replacement processes.

In a region that is to be the staircase region SR later, the stopper layer SPn that is not in contact with the slit ST and the end surfaces of the gap layer GP of the step surfaces of each step of the staircase shape is maintained as it is.

Thereafter, the insulating layer 54 is formed on the side wall of the slit ST, and the insulating layer 54 is filled with the conductive layer 24 to form the plate-shaped contact LI. However, the slit ST may be filled with the insulating layer 54 and the like without forming the conductive layer 24, and a plate-shaped member may be formed in that manner.

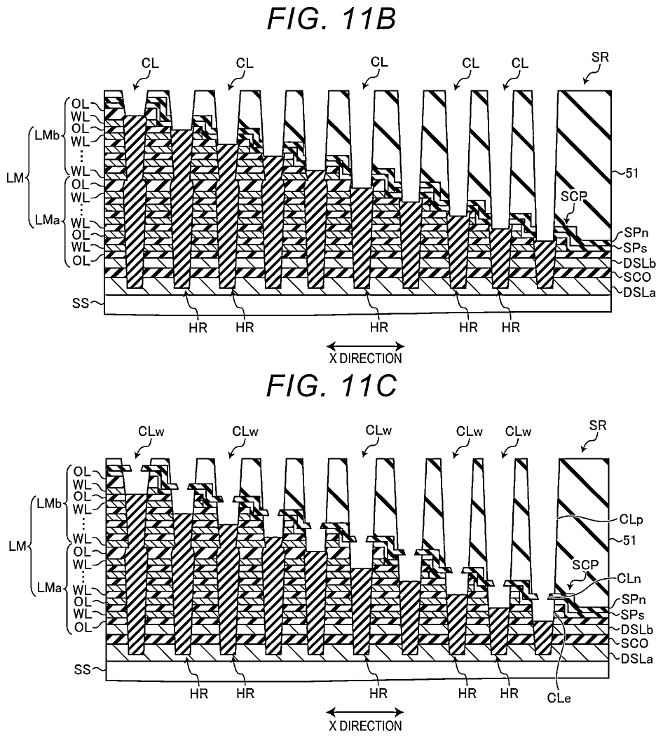

Next, a state in which the plurality of contacts CC are formed in the staircase region SR will be described with reference to FIGS. 11A to 11C. FIGS. 11A to 11C are cross-sectional views along the X direction of the staircase region SR, as in FIGS. 8A to 8C described above.

As illustrated in FIG. 11A, a plurality of contact holes CL that penetrates the insulating layer 51 and reaches the stopper layer SPn covering the terrace surface of each step is formed. Such processing may be performed, for example, by etching the insulating layer 51 using highly selective conditions between the insulating layer 51 and the stopper layer SPn including different materials.

In addition, in the example of FIG. 11A, it is assumed that the center point of the cross-sectional shape of the contact hole CL in the XY plane is formed at a position coinciding with one columnar portion HR. In addition, it is preferable that the contact hole CL has a diameter generally larger than a distance between the columnar portions HR adjacent to each other.

As illustrated in FIG. 11B, the stopper layers SPn and SPs are subsequently etched and removed. When the stopper layer SPn is etched, it is preferable to use highly selective conditions with respect to the stopper layer SPs of the lower layer. When the stopper layer SPs is etched, the upper end portion of the columnar portion HR below the stopper layer SPs, which contains the same material as the stopper layer SPs, is also slightly etched and removed.

Here, as illustrated in FIG. 11A, the plurality of contact holes CL reaching the word lines WL of different layers are, for example, collectively formed. At this time, the etching of the contact hole CL is temporarily stopped in the stopper layer SPn containing a material different from the insulating layer 51.

As a result, it is possible to prevent a part of the contact holes CL, which respectively have different depths to be reached, from penetrating the insulating layer OL of the columnar portion HR and the terrace surface of each step of the staircase portion SCP containing the same material as the insulating layer 51 and from being formed beyond the depth position of the target depth. Thereafter, as illustrated in FIG. 11B, the plurality of contact holes CL can be respectively reached to the depth position of the target depth with high accuracy by gradually removing the stopper layers SPn and SPs.

As illustrated in FIG. 11C, the bottom surface of the contact hole CL is subjected to the wet etching using a chemical solution such as diluted hydrogen fluoride (DHF). Thereby, the upper end portion of the columnar portion HR exposed on the bottom surface of the contact hole CL is further etched and removed, and the bottom surface of the contact hole CL reaches at least the height position of the word line WL to be connected. In the example of FIG. 11C, the bottom surface of the contact hole CL reaches the height position of the insulating layer OL immediately below the word line WL to be connected.

Here, the chemical solution such as DHF also dissolves the insulating layer 51, the stopper layer SPs, and the insulating layer OL, which contain the same material as the columnar portion HR. Therefore, the diameter of the penetrating portions of the insulating layer 51, the stopper layer SPs, and the insulating layer OL of the contact hole CL is enlarged. In addition, since the chemical solution such as DHF also dissolves the metal layer such as the tungsten layer, the diameter of the contact hole CL may be enlarged even in the portion that penetrates the word line WL to be connected.

On the other hand, the stopper layer SPn penetrating the contact hole CL is, for example, a silicon nitride layer, and the removal rate by the chemical solution such as the DHF is lower than that of the insulating layer 51, the stopper layer SPs, and the insulating layer OL, which are the silicon oxide layers. Therefore, the diameter of the penetrating portion of the stopper layer SPn of the contact hole CL is hardly enlarged.

Thereby, a contact hole CLw having a diameter of the penetrating portion of the stopper layer SPn smaller than that of the others is formed. That is, the contact hole CLw has an extension portion CLp that penetrates the insulating layer 51, a penetrating portion CLn that has a diameter smaller than that of other portions and penetrates the stopper layer SPn, and a connection portion CLe that penetrates the stopper layer SPs, the insulating layer OL, and the like and reaches the word line WL.

Thereafter, each of the contact holes CLw is filled with the conductive layer 25 such as a tungsten layer. As a result, a plurality of contacts CC including an extension portion CCp extending within the insulating layer 51, a penetrating portion CCn having a smaller diameter than the extension portion CCp, and a connection portion CCe having a larger diameter than the penetrating portion CCn and connected to the word line WL are obtained.

Thereafter, the insulating layer 52 is formed on the upper surface of the insulating layer 51 covering the upper surface of the stacked body LM and the staircase region SR, and the plug V0 penetrating the insulating layer 52 and connected to the contact CC is formed. In addition, a plug CH penetrating the insulating layer 52 and connected to the pillar PL is formed. Further, the insulating layer 53 is formed on the insulating layer 52 to form the upper layer wiring MX, the bit line BL, and the like connected to the plug V0 and the plug CH. In addition, an electrode pad, or the like that is electrically connected to the peripheral circuit CBA is formed on the upper surface of the insulating layer 53.

Moreover, for example, the plugs V0 and CH, the upper layer wiring MX, the bit line BL, and the like may be collectively formed by using a dual damascene method or the like.

In addition, the peripheral circuit CBA is formed on a semiconductor substrate SB separate from the supporting substrate SS on which the stacked body LM is formed, and is covered with the insulating layer 40. A contact, a via, a wiring, and the like for drawing out the peripheral circuit CBA to the surface of the insulating layer 40 are formed in the insulating layer 40 and are connected to the electrode pad and the like formed on the upper surface of the insulating layer 40.

Subsequently, the supporting substrate SS and the semiconductor substrate SB are bonded to each other by the insulating layers 50 and 40 provided in each of the supporting substrate SS and the semiconductor substrate SB, and the electrode pads in the insulating layers 50 and 40 are connected to each other. Thereafter, the supporting substrate SS is removed to expose the source line SL, and the electrode film EL is connected via the insulating layer 60 in which the plug PG is formed.

As described above, the semiconductor storage device 1 of the embodiment is manufactured.

### Comparative Example

The semiconductor storage device such as a three-dimensional non-volatile memory is manufactured through a process of forming a stacked body in which a plurality of word lines are stacked by replacing, for example, a stacked body in which a sacrificial layer is stacked in multiple layers. Thereafter, a process of forming a contact in a terrace portion from which electrical connection to the plurality of word lines are drawn out in a staircase shape is performed.

In addition, a plurality of columnar portions may be formed in the staircase portion of the semiconductor storage device in order to support the structure of the stacked body when the stacked body is replaced. At this time, the location of the columnar portion is adjusted so that the columnar portion does not interfere with the contact, at least by not disposing the columnar portion at the disposition location of the contact.

However, in such a case, the density of the columnar portion per unit area cannot be sufficiently increased, and the stacked body being replaced may be distorted or collapsed.

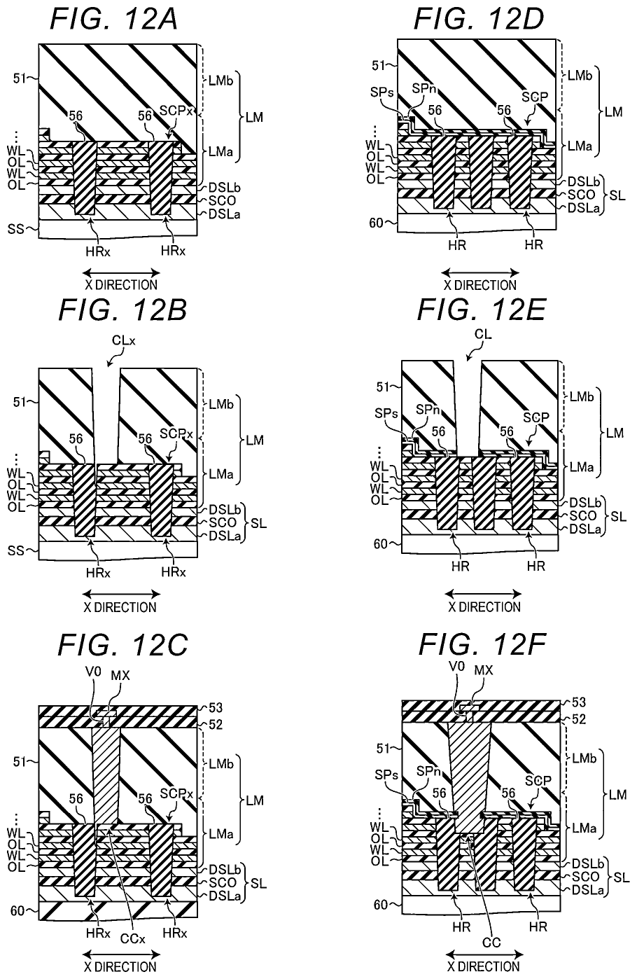

In addition, even when the columnar portion is formed while avoiding interference with the contact as described above, a misalignment may occur when the contact is formed, or the contact is inclined, and it is difficult to sufficiently prevent the interference between the contact and the columnar portion. When the contact and the columnar portion are in contact with each other, a short circuit may occur between the word lines due to poor formation of the contact. FIGS. 12A to 12F show an example when a misalignment occurs in the contact in the comparative example and the embodiment.

FIGS. 12A to 12F are enlarged cross-sectional views along the X direction illustrating the formation process of the contacts CC and CCx of the semiconductor storage device according to the embodiment and the comparative example. FIGS. 12A to 12C show the processing of the comparative example, and FIGS. 12D to 12F show the processing of the embodiment.

As illustrated in FIG. 12A, in the processing of the comparative example, the insulating layer 51 is directly formed on a staircase portion SCPx.

In addition, in the comparative example, a columnar portion HRx is disposed to avoid interference with the contact CCx by reducing the disposition density of the columnar portion HRx around the position at which the contact CCx is at least formed. In the example of FIG. 12A, the contact CCx is intended to be formed at a position between the two columnar portions HRx illustrated in the figure, avoiding interference with the columnar portion HRx.

As illustrated in FIG. 12B, a contact hole CLx penetrates the insulating layer OL of the terrace surface of the insulating layer 51 and a staircase portion SCPx and to directly reach the word line WL to be connected. In the example of FIG. 12B, however, a misalignment occurs in the contact hole CLx, and a part of the columnar portion HRx on the left side on the paper is in contact.

At this time, a part of the lower end portion of the contact hole CLx may reach a layer lower than the word line WL, which is the target to be connected, via the columnar portion HRx. In the example of FIG. 12B, the lower end portion of the contact hole CLx reaches the word line WL in the lower layer of the word line WL to be connected.

As illustrated in FIG. 12C, the contact hole CLx which partially reaches the lower layer is filled with the conductive layer, and the contact CCx is formed. In the example of FIG. 12C, the lower end portion of the contact CCx is connected to both the word line WL to be connected and the word line WL in the lower layer thereof, and a short circuit occurs between these word lines WL.

As illustrated in FIG. 12D, in the processing of the embodiment, as described above, the insulating layer 51 is formed on the staircase portion SCPx via the stopper layers SPs and SPn.

In addition, in the embodiment, even in the vicinity of the position where the contact CC is formed, the periodicity of the columnar portion HR is maintained, and the columnar portions HR are arranged at a high density. In the example of FIG. 12D, the contact CC is intended to be formed at a position overlapping the columnar portion HR in the center of the three columnar portions HR illustrated in the figure.

As illustrated in FIG. 12E, the contact hole CL penetrating the insulating layer 51 is formed with the stopper layer SPn as a stopper. In addition, the stopper layers SPn and SPS are subsequently etched and removed so that the bottom surface of the contact hole CL reaches to the insulating layer OL, which is a terrace surface.

However, in the example of FIG. 12E, the contact hole CL is formed at a position where the contact hole CL is partially overlapped with each of the columnar portions HR on the left side and the center on the paper due to the misalignment in the contact hole CL.

However, in the processing of the embodiment, even when the misalignment occurs as described above, the etching of the contact hole CL is temporarily stopped by the stopper layer SPn. Therefore, the lower end portion of the contact hole CL is prevented from reaching a layer lower than the word line WL, which is to be connected, via the columnar portion HR.

Thereafter, not illustrated in the drawing, the contact hole CLw (refer to FIGS. 11A to 11C) is formed by wet etching, which penetrates the upper end portions of the insulating layer OL and the columnar portion HR and reaches the word line WL to be connected. At this time, a part or all of the word line WL to be connected located between the two columnar portions HR may be penetrated.

As illustrated in FIG. 12F, the contact hole CLw that is subjected to the wet etching process is filled with the conductive layer, and the contact CC is formed. A lower end portion of the contact CC penetrates the word line WL to be connected and is stopped by the lower insulating layer OL. In this way, even when the misalignment or the like occurs in the contact CC and the columnar portion HR comes into contact with the contact CC, a short circuit between the word lines WL is prevented.

According to the semiconductor storage device 1 of the embodiment, the plurality of columnar portions HR are arranged with periodicity in two directions intersecting each other when viewed in the stacking direction of the stacked body LM, and the contact CC has a diameter larger than a distance between the plurality of columnar portions HR.

In this way, regardless of the size and the disposition location of the contact CC, by disposing the plurality of columnar portions HR with maintaining the periodicity, the disposition density of the columnar portions HR can be increased, and the distortion and the collapse of the stacked bodies LMga and LMgb being replaced can be prevented.

According to the semiconductor storage device 1 of the embodiment, the contact CC is in contact with a part or the entire upper end portion and a part or the entire lower end portion of the at least one columnar portion HR. In this way, by allowing interference between the contact CC and the columnar portion HR, the periodicity of the columnar portion HR can be maintained, and the columnar portion HR can be arranged at a high density.

According to the semiconductor storage device 1 of the embodiment, the stopper layer SPn that covers above the staircase portion SCP along the staircase shape of the staircase portion SCP and the insulating layer 51 that is provided with a material different from a material of the stopper layer SPn, covers the staircase portion SCP via the stopper layer SPn, and reaches at least a height position of the upper surface of the stacked body LM are further provided.

In this way, by interposing the stopper layer SPn, which acts as a stopper when the contact hole CL is formed, between the insulating layer 51 and the staircase portion SCP, the contact hole CL is prevented from being formed beyond the reaching depth even when the contact hole CL is in contact with the columnar portion HR. Therefore, a configuration that allows interference between the contact CC and the columnar portion HR can be adopted.

According to the semiconductor storage device 1 of the embodiment, the stopper layer SPn covers the staircase portion SCP through the stopper layer SPs containing the same material as the insulating layer 51. Thereby, when the stacked body LM is replaced, the end surface of the insulating layer NL provided in the step surface is covered with the stopper layer SPs. Therefore, the stopper layer SPn is prevented from being replaced via the insulating layer NL of the step surface.

According to the semiconductor storage device 1 of the embodiment, the plate-shaped contact LI that extends in the direction along the stacking direction of the stacked body LM and the X direction and divides the stacked body LM in the direction along the Y direction is further provided, and the stopper layer SPn covers the staircase portion SCP of the portion other than the disposition location of the plate-shaped contact LI. As a result, when the stacked body LM is replaced, the stopper layer SPn is prevented from being replaced via the slit ST.

Further, in the above-described embodiment, the staircase region SR including the staircase portion SCP is disposed at both end portions of the stacked body LM in the X direction. However, for example, a staircase region including a staircase portion formed by digging a central portion of the stacked body in a mortar shape may be disposed in the stacked body.

In addition, in the above-described embodiment, the peripheral circuit CBA that contributes to the operation of the memory cell MC is disposed on the semiconductor substrate SB above which the stacked body LM is bonded. However, the stacked body may be stacked on the peripheral circuit, which is disposed on the semiconductor substrate and includes the transistor. Alternatively, the stacked body may be disposed on the same semiconductor substrate as the peripheral circuit.

In addition, in the above-described embodiment, the semiconductor storage device 1 includes a stacked body LM of 2 tiers including stacked bodies LMa and LMb. However, the semiconductor storage device may include a stacked body of 1 tier or 3 tiers or more. Note that in a multi-tier type semiconductor storage device, the number of layers of the word line WL may be further increased.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a stacked body in which a plurality of conductive layers are stacked one layer apart from each other and which has a staircase portion in which the plurality of conductive layers have been processed into a staircase shape;
a first pillar that extends in a stacking direction of the stacked body in a portion of the stacked body different from the staircase portion and forms memory cells at each intersection between the first pillar and at least a part of the plurality of conductive layers;
a plurality of second pillars that are arranged with periodicity in the staircase portion and extend in the stacking direction within the stacked body; and
a contact that is disposed in the staircase portion and that is electrically connected to one of the plurality of conductive layers,
wherein the contact has a diameter larger than a distance between the plurality of second pillars.

2. The semiconductor storage device according to claim 1,
wherein a part or the entirety of a lower end portion of the contact is in contact with a part or the entirety of an upper end portion of at least one second pillar among the plurality of second pillars.

3. The semiconductor storage device according to claim 1,
wherein the contact has a diameter at an upper portion thereof that is larger than a diameter of each of the plurality of second pillars at an upper end portion thereof.

4. The semiconductor storage device according to claim 1,
wherein the plurality of second pillars are arranged with periodicity in two directions intersecting each other when viewed in the stacking direction.

5. The semiconductor storage device according to claim 1, further comprising:
a first insulating layer that covers an upper portion of the staircase portion along a staircase shape of the staircase portion; and
a second insulating layer that contains a material different from a material of the first insulating layer, covers the staircase portion via the first insulating layer, and reaches at least a height position of an upper surface of the stacked body.

6. The semiconductor storage device according to claim 5,
wherein the contact includes
a first portion that penetrates the second insulating layer and has a first diameter at a lower end portion thereof,
a second portion that penetrates the first insulating layer and has a second diameter smaller than the first diameter, and
a third portion that is electrically connected to one of the plurality of conductive layers and has a third diameter at an upper end portion thereof that is larger than the second diameter.

7. A method for manufacturing a semiconductor storage device, the method comprising:
forming a first stacked body in which a plurality of sacrificial layers are stacked one layer apart from each other;
forming a first pillar that includes a semiconductor layer extending in a stacking direction of the first stacked body within the first stacked body in a first region of the first stacked body, and a plurality of second pillars with periodicity that extend in the stacking direction within the first stacked body in a second region of the first stacked body;
forming, in the second region, a staircase portion in which the plurality of sacrificial layers have been processed into a staircase shape;
forming memory cells in each intersection of the first pillar and at least a part of the plurality of conductive layers by replacing the plurality of sacrificial layers with the plurality of conductive layers; and
forming a contact having a diameter larger than a distance between the plurality of second pillars and to be in contact with one of the plurality of conductive layers in the staircase portion.

8. The method for manufacturing a semiconductor storage device according to claim 7,
wherein a part or the entirety of a lower end portion of the contact is formed at a position that is in contact with a part or the entirety of an upper end portion of the at least one second pillar among the plurality of second pillars.

9. The method for manufacturing a semiconductor storage device according to claim 7,
wherein, when forming the staircase portion, a first insulating layer that covers an upper portion of the staircase portion along a staircase shape of the staircase portion is formed, and then a second insulating layer that contains a material different from a material of the first insulating layer, covers the staircase portion via the first insulating layer, and reaches at least a height position of an upper surface of the first stacked body is formed.

10. The method for manufacturing a semiconductor storage device according to claim 9,
wherein, when forming the contact, a contact hole penetrating the second insulating layer is formed with the first insulating layer as a stopper, and then the contact hole is further formed to penetrate the first insulating layer.

11. The method for manufacturing a semiconductor storage device according to claim 10,
wherein, when forming the contact, a bottom surface of the contact hole penetrating the first and second insulating layers is subjected to wet etching to expose one of the plurality of conductive layers to which the contact is to be electrically connected.

12. The method for manufacturing a semiconductor storage device according to claim 7,
wherein, when forming the contact, the contact hole is filled with a conductive layer.

13. The method for manufacturing a semiconductor storage device according to claim 7, wherein the formed contact includes
a first portion having a first diameter at a lower end portion thereof,
a second portion having a second diameter smaller than the first diameter, and
a third portion that is electrically connected to the one of the plurality of conductive layers and has a third diameter at an upper end portion thereof that is larger than the second diameter.

14. A semiconductor storage device comprising:
a stacked body in which a plurality of conductive layers are stacked one layer apart from each other and which has a staircase portion in which the plurality of conductive layers have been processed into a staircase shape;
a first pillar that extends in a stacking direction of the stacked body in a portion of the stacked body different from the staircase portion and forms memory cells at each intersection between the first pillar and at least a part of the plurality of conductive layers;
a plurality of second pillars that are arranged to be equidistant from each other in the staircase portion and extend in the stacking direction within the stacked body; and
a contact that is disposed in the staircase portion and that is electrically connected to one of the plurality of conductive layers, the contact having a first portion that penetrates an insulating layer of the staircase portion, a second portion that extends in the stacking direction from the lower end portion of the first portion, and a third portion that extends in the stacking direction from the lower end portion of the second portion and is electrically connected to one of the plurality of conductive layers,
wherein a cross-section of the contact taken in a plane that is orthogonal to the stacking direction is larger at the lower end portion of the first portion than at any portion of the second portion and is larger at an upper end portion of the third portion than at any portion of the second portion.

15. The semiconductor storage device according to claim 14, wherein the contact is aligned with one of the second pillars in the stacking direction.

16. The semiconductor storage device according to claim 15, wherein the cross-section of an upper end portion of the contact taken in the plane that is orthogonal to the stacking direction is larger than a cross-section of an upper end portion of the second pillar that is aligned therewith in the stacking direction, that is taken in the plane that is orthogonal to the stacking direction.

17. The semiconductor storage device according to claim 16, wherein the contact has a dimension in a direction that is orthogonal to the stacking direction that is larger than a distance between the plurality of second pillars.

18. The semiconductor storage device according to claim 14, wherein the insulating layer of the staircase portion includes:
a first insulating layer that covers an upper portion of the staircase portion along a staircase shape of the staircase portion; and
a second insulating layer that contains a material different from a material of the first insulating layer, covers the staircase portion via the first insulating layer, and reaches at least a height position of an upper surface of the stacked body.
